(19) United States
(12) Patent Application Publication
(10) Pub. No.: US 2006/0087820 A1
(43) Pub. Date: Apr. 27, 2006

(54) Layout structure of a printed circuit board

(76) Inventors: Shun-Chieh Yang, Sinjhuang City (TW); Hsin-Nan Lin, Gueishan Township (TW); Chun-Ming Shen, Banciao City (TW)

Correspondence Address: RABIN & Berdo, PC, 1101 14TH STREET, NW, SUITE 500, WASHINGTON, DC, 20005, US

(21) Appl. No.: 11/106,653

(22) Filed: Apr. 15, 2005

(30) Foreign Application Priority Data
Oct. 21, 2004 (TW) 93132035

(51) Int. Cl. H05K 7/06

(52) U.S. Cl. 361/760; 361/782; 361/783

(57) ABSTRACT

A layout structure of a printed circuit board includes a thermal device, a temperature sensing device and an opening. The temperature sensing device is for sensing the environmental temperature of the printed circuit board. The opening is located between the temperature sensing device and the thermal device for reducing the extent of heat propagated from the thermal device to the temperature sensing device.

This application claims the benefit of Taiwan application Serial No. 93132035, filed Oct. 21, 2004, the subject matter of which is incorporated herein by reference.

### BACKGROUND OF THE INVENTION

1. Field of the Invention

The invention relates in general to a layout structure of a printed circuit board, and more particularly to a layout structure of a printed circuit board having a temperature sensing device.

2. Description of the Related Art

Most of present electronic and electrical devices, no matter information products, household appliances or industrial products, can adjust the rotational speed of interior heat-sink motor according to different environmental temperature, for example, control the motor to operate in a low speed mode at normal temperature and in a high speed mode at high temperature. Ordinarily, a temperature sensing device is disposed in the electronic and electrical device for sensing the environmental temperature and integrated with other electronic devices on a piece of printed circuit board.

FIG. 1 is a structure diagram of the conventional printed circuit board. Referring to FIG. 1, the printed circuit board 100 includes a temperature sensing device 110 and an electronic device 120. The temperature sensing device 110 is used to sense the environmental temperature of the printed circuit board 100 and the rotational speed of the above-mentioned heat-sink motor can be adjusted according to the environmental temperature. Generally, there are other electronic devices 120 disposed on the same printed circuit board 100, which can also generate heat due to the electronic signal loading. The heat H will be easily propagated to the temperature sensing device 110 via the printed circuit board 100, and thereby influences the accuracy of environmental temperature sensed by the temperature sensing device 110.

Using an extra printed circuit board to configure the temperature sensing device 110 independently may solve the above-mentioned problem, but it consequently increases the material and fabrication cost.

### SUMMARY OF THE INVENTION

It is therefore an object of the invention to provide a layout structure of a printed circuit board. Partial regions of the printed circuit board between the temperature sensing device and other thermal devices are hollowed out in order to reduce the extent of heat propagated to the temperature sensing device from the thermal devices via the printed circuit board. Therefore, the accuracy of environmental temperature sensed by the temperature sensing device can be improved.

The invention achieves the above-identified object by providing a layout structure of a printed circuit board including a thermal device, a temperature sensing device and an opening. The thermal device, disposed on the printed circuit board, is an electronic device or a mechanic device which will generate heat whether on purpose or not. The temperature sensing device is disposed on the printed circuit board for sensing the environmental temperature of the printed circuit board. The opening is formed by hollowing out a region of the printed circuit board provided that no circuit is disconnected accordingly, and the opening is located between the temperature sensing device and the thermal device for reducing the extent of heat propagated to the temperature sensing device from the thermal device. Therefore, the accuracy of environmental temperature sensed by the temperature sensing device can be improved.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a structure diagram of the conventional printed circuit board.

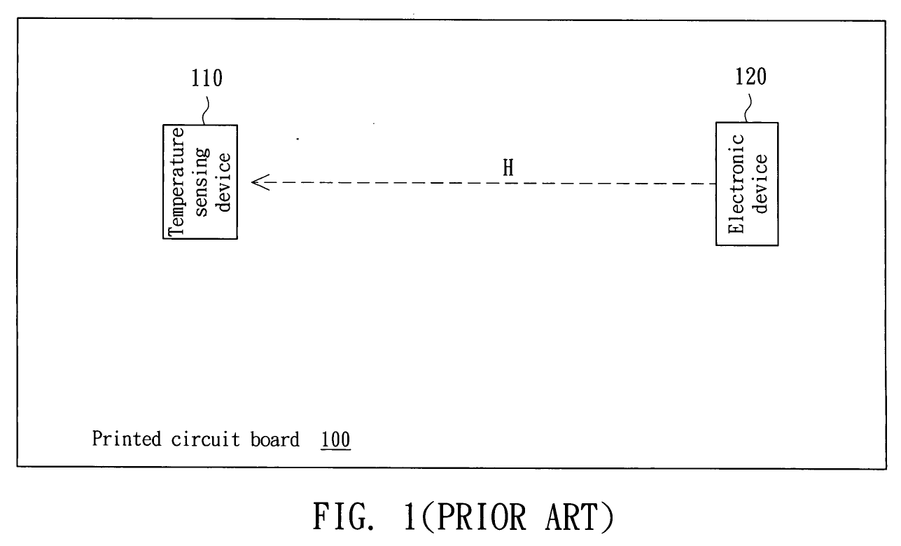

FIG. 2A is a diagram of a printed circuit board layout structure according to a preferred embodiment of the invention.

FIG. 2B is a diagram of the printed circuit board layout structure having another opening shape in FIG. 2A.

### DETAILED DESCRIPTION OF THE INVENTION

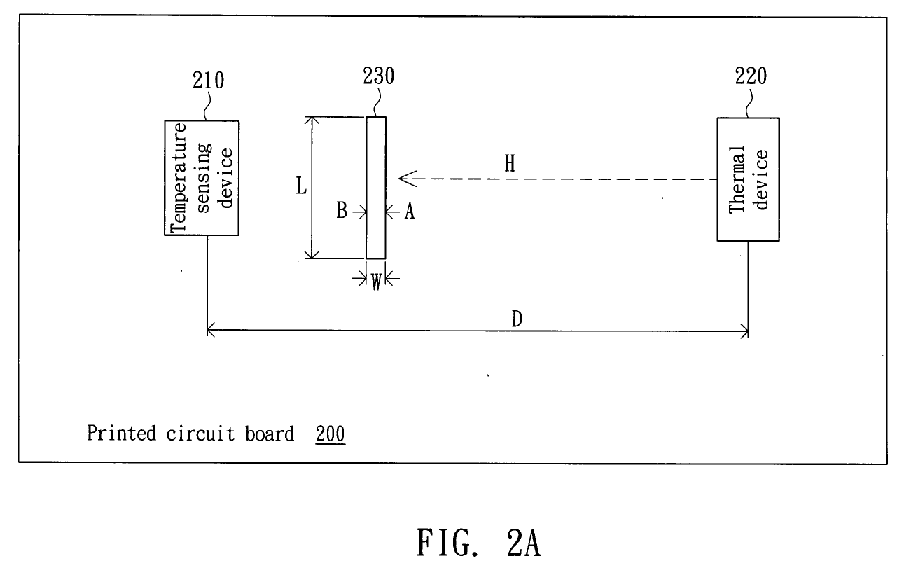

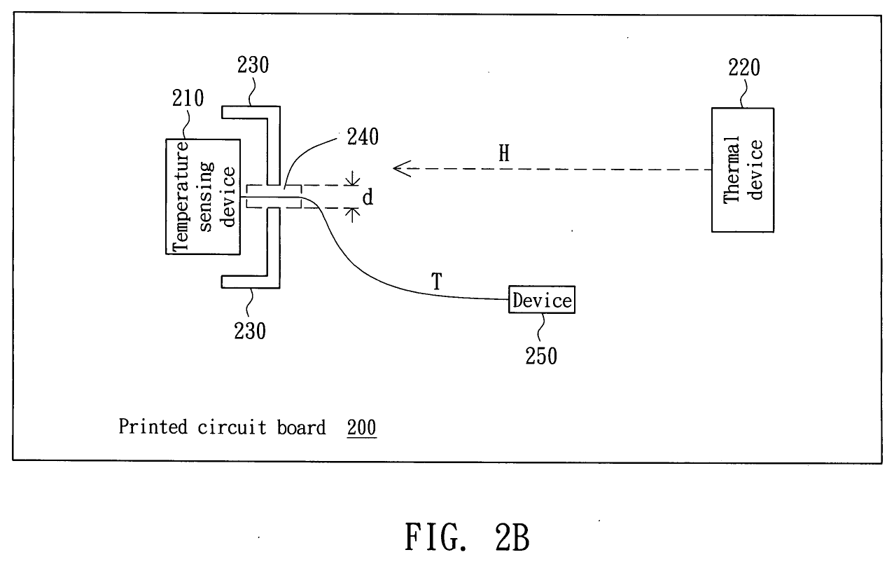

Referring to FIG. 2A, a diagram of a printed circuit board layout structure according to a preferred embodiment of the invention is shown. The printed circuit board 200, for example, used in the electronic and electrical devices like CD-ROM players, projectors, or rear projection TV (RPTV), has a layout structure including a temperature sensing device 210, a thermal device 220, and an opening 230. The temperature sensing device 210, which can be an integrated circuit or a thermistor, is disposed on the printed circuit board 200 for sensing the environmental temperature of the printed circuit board 200. The temperature sensing device 210 can be disposed onto the printed circuit board 200 by a surface mounted design (SMD) structure or a pin through hole (PTH) structure. The thermal device 220, disposed on the printed circuit board 200, is an electronic device or a mechanic device, which will release heat whether on purpose or not, such as a metal heat sink. The opening 230 is formed by hollowing out a region of the printed circuit board, provided that no circuit is disconnected accordingly. The opening 230 is disposed between the temperature sensing device 210 and the thermal device 220 for reducing the extent of heat propagated to the temperature sensing device 210 from the thermal device 220.

When the heat H generated by the thermal device 220 is propagated to the side A of the opening 230 via the printed circuit board 200, it is difficult for the heat H to pass the opening 230 and continuously go forward to the temperature sensing device 210, because the opening 230 can cut off the shortest path of the heat H to reach the side B and go forward to the temperature sensing device 210 by providing good heat insulation effect through air convection. Therefore, the design of the opening 230 can help to reduce the extent of the heat H propagated to the temperature sensing device 210 from the thermal device 220, and thereby reduces interference in the environmental temperature sensing of the temperature sensing device 210.

As shown in FIG. 2A, the opening 230 is in a slot shape, whose length L and width W can be adjusted according to the mechanic specifications of the temperature sensing device 210 and the thermal device 220, the distance D between the sensing device 210 and the thermal device 220, and the material intensity of the printed circuit board 200, etc. Generally speaking, the larger the temperature sensing device 210 or the thermal device 220 is, the greater the length L of the opening 230 should be. Or the smaller the distance D between the temperature sensing device 210 and the thermal device 220 is, the greater the length L and the width W of the opening 230 should also be. In addition, the scale of opening 230 can be adjusted according to the material intensity of the printed circuit board 200 so as to prevent the printed circuit board 200 from being broken as shaken or dropped. Therefore, the opening 230 of the invention can be applied to the printed circuit board 200 made of various materials.

The opening 230 can also be a L-shaped opening surrounding the temperature sensing device 210, and the two openings 230 are symmetrical to the temperature sensing device 210 in the layout as shown in FIG. 2B. It should be noted especially that a channel 240, a region not hollowed out, is formed between the two L-shaped openings 230. The width d of the channel 240 can be designed to reduce the heat passing through the channel 240 directly and reaching the temperature sensing device 210 meanwhile the channel 240 can be provided for configuring a circuit trace T to connect the temperature sensing device 210 and other devices 250. Moreover, the opening 230 is disposed on the printed circuit board 200 closer to the temperature sensing device 210 than to the thermal device 220. Therefore, the printed circuit board 200 of the invention can reduce not only the extent of the heat propagated from the thermal device 220 to the temperature sensing device 210 but also the extent of heat propagated from other devices (not shown in FIG. 2B) at the same side of the thermal device 220 to the temperature sensing device 210.

As mentioned above, although the opening 230 in a slot shape or an L-hole shape surrounding the temperature sensing device is taken as an example in the invention, the shape and area of the opening 230 of the printed circuit board 200 is not limited thereto. The opening 230 can also be in any other shape and has any other area. As long as the region surrounding the temperature sensing device 210, which is not hollowed out, can provide the wire configuration to couple the temperature sensing device 210 and other devices or circuits, the printed circuit board 200 can still have enough structure intensity, and the purpose of reducing heat propagated from the thermal device 220 to the temperature sensing device 210 can be achieved, it will be not apart from the skill scope of the invention.

Furthermore, the printed circuit board 200 can also be a multi-layer printed circuit board and the temperature sensing circuit 210 and the thermal device 220 can be respectively disposed at different wiring layers. The opening 230 design of the printed circuit board 200 in the invention can still reduce the extent of heat propagated from the thermal device 220 disposed at a different wiring layer to the temperature sensing device 210 and thereby achieves the purpose of providing accurate environmental temperature.

The printed circuit board disclosed by the above-mentioned embodiment has the following advantages. By partially hollowing out the regions of the printed circuit board between the temperature sensing device and the thermal device and cutting off the heat propagating path via air convection, the extent of heat propagated from the thermal device to the temperature sensing device can be reduced and the accuracy of environmental temperature sensed by the temperature sensing device can be improved effectively.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A layout structure of a printed circuit board, comprising:
a thermal device, disposed on the printed circuit board;
a temperature sensing device, disposed on the printed circuit board; and
an opening, located on the printed circuit board and between the temperature sensing device and the thermal device.

2. The layout structure of a printed circuit board according to claim 1, wherein the opening is located closer to the temperature sensing device than to the thermal device.

3. The layout structure of a printed circuit board according to claim 1, wherein the opening is a slot.

4. The layout structure of a printed circuit board according to claim 1, wherein the opening is disposed surrounding the temperature sensing device.

5. The layout structure of a printed circuit board according to claim 4, wherein the opening is an L-shaped opening.

6. The layout structure of a printed circuit board according to claim 4, wherein the printed circuit board further comprises another opening located between the temperature sensing device and the thermal device, and surrounding the temperature sensing device, and a channel is formed between the two openings.

7. The layout structure of a printed circuit board according to claim 6, wherein the openings are disposed symmetrically to the temperature sensing device.

8. The layout structure of a printed circuit board according to claim 1, wherein the scale of the opening is determined according to the scale of the temperature sensing device.

9. The layout structure of a printed circuit board according to claim 1, wherein the scale of the opening is determined according to the scale of the thermal device.

10. The layout structure of a printed circuit board according to claim 1, wherein the scale of the opening is determined according to a distance between the temperature sensing device and the thermal device.

11. The layout structure of a printed circuit board according to claim 1, wherein the temperature sensing device is of a surface mounted design (SMD) structure.

12. The layout structure of a printed circuit board according to claim 1, wherein the temperature sensing device is of a pin through hole (PTH) structure.

13. The layout structure of a printed circuit board according to claim 1, wherein the temperature sensing device is an integrated circuit.

14. The layout structure of a printed circuit board according to claim 1, wherein the temperature sensing device is a thermistor.

15. The layout structure of a printed circuit board according to claim 1, wherein the printed circuit board is a multi-layer printed circuit board.

16. The layout structure of a printed circuit board according to claim 1, wherein the printed circuit board is a single-layer printed circuit board.
